(19) United States
(12) Patent Application Publication
(10) Pub. No.: US 2024/0393678 A1
(43) Pub. Date: Nov. 28, 2024

(54) REMOVING METHOD, REMOVAL APPARATUS, IMPRINT APPARATUS, REPLICA MANUFACTURING APPARATUS, AND ARTICLE MANUFACTURING METHOD

(71) Applicant: CANON KABUSHIKI KAISHA, Tokyo (JP)

(72) Inventors: Keiko ABE, Kanagawa (JP); Yo WATANABE, Tokyo (JP); Eiko ASAMI, Kanagawa (JP); Noriyasu HASEGAWA, Tochigi (JP); Yuichi IWASAKI, Tochigi (JP); Jun KATO, Kanagawa (JP)

(21) Appl. No.: 18/639,187

(22) Filed: Apr. 18, 2024

(30) Foreign Application Priority Data
May 26, 2023 (JP) 2023-086963

(51) Int. Cl. G03F 1/82; G03F 1/48; G03F 7/00

(52) U.S. Cl. CPC G03F 1/82; G03F 1/48; G03F 7/0002

(57) ABSTRACT

A removing method that makes it possible to remove a residual generated at least near a side surface of a convex portion of a mold. The removing method is a removing method of removing a residual attached to a mold which includes a base having a main surface and a convex portion provided on the main surface and in which a concavo-convex pattern formed on an upper surface of the convex portion is pressed against a curable composition, the removing method includes removing the residual, and the removing of the residual includes removing the residual by dissolving a liquid-repellent layer formed on at least a side surface of the convex portion with a predetermined solvent.

### BACKGROUND OF THE INVENTION

### Field of the Invention

The present invention relates to a removing method, a removal apparatus, an imprint apparatus, a replica manufacturing apparatus, and an article manufacturing method.

### Description of the Related Art

Optical nanoimprint technology is attracting attention as a method of forming nano-sized (for example, 1 nm or more and 1000 nm or less) fine patterns (concavo-convex structures). In optical nanoimprint technology, an imprint mold (die, mask) that has a concavo-convex pattern and is transparent to exposure light is brought into contact with a curable composition (resist, imprint material) coated on a base substrate. After the curable composition is cured to form a cured material, the mold is released from the cured material to form a cured material pattern on the base substrate. Then, the base substrate is processed using the cured material pattern as a mold to form a fine pattern on the base substrate. In the imprint method, a process of forming a cured material pattern at a desired position on a substrate is repeated while moving a mold on the substrate.

Molds used in optical nanoimprint technology may be formed by processing materials such as quartz glass. An imprint mold forms a convex mesa portion and forms a fine concavo-convex pattern on a surface in contact with a curable composition (imprint surface) which is an upper surface of the mesa portion. This concavo-convex pattern will be pressed against the curable composition.

Here, at a point in time when the concavo-convex pattern formed on the upper surface of the mesa portion of the mold is pressed against the curable composition, the curable composition has fluidity. For this reason, the curable composition may protrude outward from the contact surface (imprint surface) on the upper surface of the mesa portion and creep up onto a mesa side wall (hereinafter, this phenomenon will be referred to as “oozing”).

The mold is separated from the cured material on the substrate when the curable composition is cured, but the curable composition that has oozed out onto the mesa side wall remains attached to the mesa side wall. For this reason, when a process of pressing the mold against the curable composition is repeated, there is a problem that the amount of curable composition that adheres to the mesa sidewall gradually increases, and eventually the curable composition falls onto the substrate at an unintended timing, causing large defects on the substrate.

Japanese Patent No. 6441181 discloses technology for making only mesa sidewalls liquid-repellent to a curable composition by protecting a concavo-convex pattern surface with a protective material in advance.

Japanese Patent No. 6441181 discloses a method of protecting the concavo-convex pattern surface by bringing a shielding plate extremely close to the concavo-convex pattern, or a method of protecting the concavo-convex pattern surface by bringing a mold substrate into contact with the concavo-convex pattern surface. However, even when the shielding plate is brought extremely close to the concavo-convex pattern, a liquid-repellent component will infiltrate into the concavo-convex pattern if the shielding plate does not adhere closely to the concavo-convex pattern. Furthermore, in the method of protecting the concavo-convex pattern surface by bringing the mold substrate into contact with the concavo-convex pattern surface, both an imprint mold and the mold substrate are hard solid materials, and thus it is difficult to bring a plate material into contact in the entire region to be protected. For this reason, it is not possible to prevent the liquid-repellent component from infiltrating at all locations, and a residual of a liquid-repellent material may remain on the concavo-convex pattern. Thus, in the method disclosed in Japanese Patent No. 6441181, there is a possibility that a residual of the liquid-repellent material will be generated and the residual will remain on a mesa side wall. That is, in the method disclosed in Japanese Patent No. 6441181, when a residual is generated, the residual cannot be removed.

### SUMMARY OF THE INVENTION

In order to solve the above-described problems, the present invention provides a removing method that makes it possible to remove at least residuals generated near side surfaces of convex portions of a mold.

A removing method according to one aspect of the present invention is a removing method of removing a residual attached to a mold which includes a base having a main surface and a convex portion provided on the main surface and in which a concavo-convex pattern formed on an upper surface of the convex portion is pressed against a curable composition, the removing method includes removing the residual, and the removing of the residual includes removing the residual by dissolving a liquid-repellent layer formed on at least a side surface of the convex portion with a predetermined solvent.

Further features of the present invention will become apparent from the following description of exemplary embodiments with reference to the attached drawings.

### BRIEF DESCRIPTION OF THE DRAWINGS

FIG. 1 is a cross-sectional view of a mold according to an embodiment.

FIG. 2 is a configuration diagram of a removal apparatus according to the embodiment.

FIG. 3 is a schematic diagram of a protective layer forming unit according to the embodiment.

FIG. 4 is a schematic diagram of a protective layer removal unit according to the embodiment.

FIG. 5 is a diagram for describing steps of removing residuals according to the embodiment.

FIG. 6 is a flowchart showing residual removal processing in the embodiment.

FIGS. 7A to 7D are diagrams showing an imprint method according to the embodiment.

FIGS. 8A to 8F are diagrams for describing an article manufacturing method.

### DESCRIPTION OF THE EMBODIMENTS

Hereinafter, embodiments of the present invention will be described in detail with reference to the drawings as appropriate. However, the present invention is not limited to the embodiments to be described below. Furthermore, in the present invention, modifications and improvements can be appropriately made to the embodiments to be described below based on the common knowledge of those skilled in the art without departing from the scope of the invention.

### Embodiment 1

A mold (die, mask) used for nanoimprinting is formed such that, even when parallelism between the mold and a substrate to be processed (substrate) is not perfect, a mold substrate other than a contact surface (imprint surface) with the substrate to be processed (substrate) does not contact the substrate to be processed. Specifically, the contact surface of the mold is formed to have a peripheral side wall surface and protrude from a mold base material. A convex portion where the contact surface is formed, that is, a plateau portion having a contact surface as the upper surface and a side wall surface, is referred to as a mesa portion. With such a configuration, a certain amount of clearance can be maintained between a portion other than the imprint surface of the mold and the substrate to be processed during imprinting, and it is possible to prevent the two from coming into contact with each other.

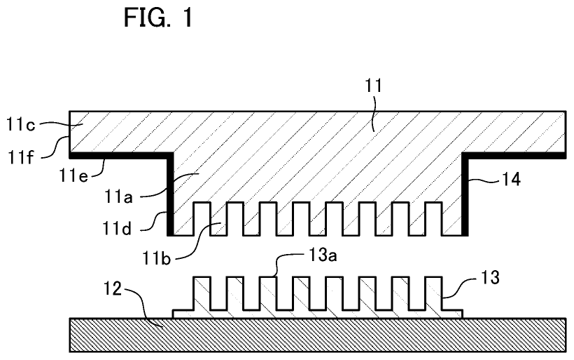

FIG. 1 is a cross-sectional view of a mold 11 in the present embodiment. Hereinafter, the mold 11 of the present embodiment in which a liquid-repellent layer is formed and residuals are removed, and a method of removing residuals adhering to the mold (a mold-cleaning method) for forming the mold 11 will be described with reference to FIG. 1.

As shown in FIG. 1, the mold 11 according to the present embodiment has a mesa portion (convex pattern forming portion) 11a, and a fine concavo-convex pattern (pattern portion) 11b is formed on a lower surface (imprint surface) of the mesa portion 11a. By pressing the concavo-convex pattern 11b onto a curable composition 13 on a substrate 12, the concavo-convex pattern 11b is transferred to the curable composition 13, thereby forming a curable composition pattern 13a. That is, the mold 11 in the present embodiment has a base having a main surface and a convex portion provided on the main surface, and a concavo-convex pattern that is pressed against the curable composition is formed on an upper surface of the convex portion. The mold 11 is formed of, for example, quartz.

When the concavo-convex pattern 11b of the mold 11 is pressed against the curable composition 13, the curable composition 13 may protrude to the outside of the imprint surface and creep up and adhere to a side wall 11d of the mesa portion 11a. In order to prevent this, the mold 11 in the present embodiment has a liquid-repellent layer 14 with a liquid-repellent surface formed on the side wall 11d of the mesa portion 11a. The liquid-repellent layer 14 is formed to have a certain thickness. The liquid-repellent layer 14 is a film (liquid-repellent layer) that has a higher contact angle with the curable composition 13 than the surface material of the mold 11 on which the liquid-repellent layer 14 is formed, such as quartz. The liquid-repellent layer is preferably formed by a wet method in which a liquid material is applied and dried.

A method of forming the liquid-repellent layer 14 will be described later, but in the present embodiment, the liquid-repellent layer 14 is formed on at least the side wall of the mold 11 (the side wall 11d of the mesa portion 11a) when forming the liquid-repellent layer 14. Thereby, when the mold 11 is pressed against the curable composition 13 on the substrate 12 as described above, the curable composition 13, which is an organic material, can be prevented from creeping up onto the side wall of the mold 11. The liquid-repellent layer 14 may also be formed on an upper surface 11e and a side wall 11f of a base portion 11c of a base material that supports the mesa portion 11a, or the liquid-repellent layer 14 may be formed on at least the side wall 11d of the mesa portion 11a as described above.

Here, when the liquid-repellent layer 14 is formed on the side wall 11d of the mesa portion 11a, it is necessary to prevent the liquid-repellent layer from being formed on the imprint surface. This is because there is a concern that unfilled defects in the curable composition 13 may occur when the liquid-repellent layer is formed on the imprint surface. That is, the concavo-convex pattern 11b of the mold 11 may not be sufficiently filled with the curable composition.

In the method of forming the liquid-repellent layer 14 on the mold 11 in the present embodiment, the liquid-repellent layer 14 is formed by forming a protective layer on the imprint surface, forming the liquid-repellent layer 14 on the side wall 11d of the mesa portion 11a, and then removing the protective layer formed on the imprint surface. When the liquid-repellent layer 14 is formed, the protective layer is formed on the imprint surface before forming the liquid-repellent layer 14, and thus it is possible to prevent the liquid-repellent layer from being formed on the imprint surface. In addition, at this time, a slight residual of the liquid-repellent layer 14 (a residual of a liquid-repellent material) may be formed at an end of the imprint surface, and thus the liquid-repellent layer 14 (including the imprint surface of the mold 11) is finally cleaned with a predetermined solvent for dissolving the residual of the liquid-repellent component. In this manner, the processing is performed in the order of the formation of the protective layer, the formation of the liquid-repellent layer 14, the removal of the protective layer, and the cleaning of the liquid-repellent layer 14 (removal of the residual), and thus it is possible to properly form the liquid-repellent layer 14 on the side wall 11d of the mesa portion 11a of the mold 11 while removing the residual.

As a method of forming the protective layer, a method of applying a protective material to the imprint surface is preferable. For example, the protective material can be applied onto the imprint surface using a dispenser or a printing method. The protective material to be applied onto the imprint surface may be applied to at least the outer peripheral portion of the imprint surface. However, the protective material may be applied onto the entire imprint surface or may be applied to the outer peripheral portion of the imprint surface and its surroundings, and the region to which it is applied may be selected depending on the method of forming the liquid-repellent layer 14. When the protective material is applied to the outer peripheral portion of the imprint surface, the amount of the protective material can be reduced compared to when the protective material is applied onto the front surface thereof, and the time taken to apply the protective material can also be shortened.

Examples of the material for forming the protective layer (protective material) include glycerin, diglycerin, a polyacrylic acid aqueous solution, and the like, but are not particularly limited thereto. Alternatively, these materials may be used in combination.

As the method of forming the liquid-repellent layer 14, the liquid-repellent layer 14 may be formed by a dry method such as a sputtering method or a vapor deposition method, or may be formed by a wet method such as applying a liquid material and drying it. In addition, when the liquid-repellent layer 14 is formed, a wet method is more preferably used. Here, when the liquid-repellent layer 14 is formed by a dry method, the protective layer may be formed over the entire imprint surface. Further, when a method making it possible to partially form the liquid-repellent layer 14 like a wet method is used, the protective layer is formed on the outer peripheral portion of the imprint surface. Here, the protective layer may be formed not only on the outer peripheral portion but also on the entire imprint surface.

In the wet method, the liquid-repellent material forming the liquid-repellent layer 14 in the present embodiment is preferably a liquid-repellent material, and is particularly preferably a solution containing a polymer having a fluorocarbon chain and a volatile solvent that dissolves the polymer. A polymer having a fluorocarbon chain has a high contact angle with a cured composition and can form a satisfactory liquid-repellent layer. The volatile solvent that dissolves the polymer is not particularly limited as long as it is a volatile solvent that dissolves the polymer having a fluorocarbon chain. Examples of the volatile solvent include Novec 7200, Novec 7300, and the like manufactured by 3M Company, but are not particularly limited thereto. Alternatively, these materials may be used in combination.

As a method of removing the protective layer, it is preferable to remove the protective material forming the protective layer by dissolving it with water or an organic solvent. As a material for dissolving the protective material, a material in which the protective material has high solubility and that does not affect the liquid-repellent layer 14 may be selected. In addition, while the protective layer is being formed, it is possible to prevent contamination of the imprint surface such as adhesion of dust and organic matter (adhesion of foreign matter), and thus the protective layer may be removed immediately after the liquid-repellent layer 14 is formed, or may be removed immediately before imprint processing is performed.

When the liquid-repellent layer 14 is formed, a small amount of the liquid-repellent material may protrude from the edge of the convex portion, and the protruding liquid-repellent material may rise slightly along the side wall of the convex portion. When the rising portion remains as a residual on the pattern surface, problems such as poor contact on the imprint surface will occur, and thus it is necessary to remove the residual. In the present embodiment, in order to remove such a residual, removal processing (cleaning processing) for removing the residual of the liquid-repellent material generated on the surface of the liquid-repellent layer 14 and at the end of the liquid-repellent layer 14 is performed by dissolving the residual using a solvent.

As a removing method (cleaning method) for removing the residual of the liquid-repellent material forming the liquid-repellent layer 14, it is preferable to remove all unnecessary residuals by dissolving them while dissolving the surface of the liquid-repellent layer 14 by using a volatile solvent that can dissolve a liquid-repellent material component in the liquid-repellent layer 14. For this reason, it is preferable to select a material in which the liquid-repellent material has high solubility, and that can remove the residuals and does not affect the liquid-repellent layer.

As a specific method of removing residuals, for example, the mold 11 is rotated by a rotatable rotation mechanism while supplying a solvent for the liquid-repellent material from a supply head that can supply the liquid-repellent material and dissolving the protective material. Thereby, unnecessary residuals remaining around the liquid-repellent layer can be dissolved in the solvent for the liquid-repellent material and removed (spin method).

For example, the mold 11 is repeatedly immersed in the solvent for the liquid-repellent material and pulled up a plurality of times by using an immersion mechanism in which a container is filled with the solvent for the liquid-repellent material, and thus unnecessary residuals remaining around the liquid-repellent layer 14 can be dissolved in the solvent for the liquid-repellent material and removed (immersion method).

The unnecessary residuals are promptly dissolved through contact with the solvent. Here, the residuals can be removed in a cleaning time of several seconds. When the cleaning time is at least 5 seconds, all unnecessary residuals can be removed. That is, the residuals can be reliably dissolved and removed by setting the cleaning time to 5 seconds.

In addition, the surface of the liquid-repellent layer 14 itself is slightly dissolved by this cleaning (the liquid-repellent layer 14 is dissolved with a solvent to remove the residuals), but as long as the film thickness of approximately several nanometers of the liquid-repellent layer remains, necessary minimum liquid repellency is maintained. For example, when the thickness of approximately 3 nm or more of the liquid-repellent layer remains, necessary minimum liquid repellency is maintained. It is preferable that the film thickness of 10 nm or more remain, and it is more preferable that the film thickness of 15 nm or more remain because sufficient liquid repellency is exhibited.

The solvent for removing the residuals of the liquid-repellent layer 14 contains at least one of a hydrofluoroether, a perfluorocarbon, and a hydrofluorocarbon, and is liquid at room temperature (25° C.) with the following characteristics (a) to (d).
(a) Boiling point is less than 100° C.
(b) Vapor pressure at 25° C. is 5 KPa to 30 KPa
(c) Density at 25° C. is 1050 kg/m3 or more
(d) Surface tension at 25° C. is 20 mN/m or less

The hydrofluoroether (HFE) used in the present embodiment is not particularly limited. Preferably, the hydrofluoroether has a formula R1-O-R2 (where R1 is a hydrocarbon alkyl group or hydrofluorocarbon of C1 to C12, and R2 is a perfluorocarbon or hydrofluorocarbon of C1 to C12, preferably C3 to C12).

Specific examples of the hydrofluoroether include 1,1,2,2-tetrafluoroethyl-2,2,2,-trifluoroethyl ether, ethyl nonafluoroisobutyl ether, ethyl nonafluorobutyl ether, and the like. Further, examples thereof include methyl perfluoroisobutyl ether, methyl perfluorobutyl ether, HFE-347pc-f (CF3CH2OCF2CHF2), and the like. Further, examples thereof include HFC-52-13p (CF3CF2CF2CF2CF2CHF2), HFC-569sf (CF3CF2CF2CF2CH2CH3), and the like. Specific products include “Novec” manufactured by Sumitomo 3M Company, “ASAHIKLIN” manufactured by AGC Inc., ASAHIKLIN AE-3000 (AGC Inc.), ASAHIKLIN AC-2000 (AGC Inc.), and the like. Further, examples thereof include ASAHIKLIN AC-4000 (AGC Inc.), Novec HFE-7100(Sumitomo 3M Company), Novec HFE-7200 (Sumitomo 3M Company), and the like. The hydrofluoroether may be used alone or in a combination of two or more types.

Specific examples of the perfluorocarbon that can be used in the present embodiment include perfluorobutane, perfluoropentane, perfluorohexane, and the like. Further, examples thereof include perfluoroheptane, perfluorooctane, perfluorononane, perfluorodecane, and the like. Specific products include Fluorinert (Sumitomo 3M Company), Fluteck (Rhône Poulenc), Galden (Ausimont), ALPHARD (AGC Inc.), and the like. The perfluorocarbon may be used alone or in a combination of two or more types.

Specific examples of the hydrofluorocarbon include HFC-43-10mee, 1,1,1,3,3pentafluorobutane, 1,1,2,2,3,3,4-heptafluorocyclopentane, and the like. Furthermore, examples thereof include octafluorocyclopentane, 1,1,1,2,2,3,4,5,5,5-decafluoro-3-methoxy-4-trifluoromethyl-pentane, 2,3-dihydrodecafluoropentane, and the like. Specific products include “ZEORORA” manufactured by Zeon Corporation, Vertrel (Chemours-Mitsui Fluoroproducts Co., Ltd.), Solkane 365mfc (Solvay), and the like. The hydrofluorocarbon may be used alone or in a combination of two or more types.

The solvent for removing the residuals of the liquid-repellent layer 14 is preferably a volatile solvent that dissolves a polymer having a fluorocarbon chain. When the liquid-repellent material is formed, a volatile solvent evaporates, and thus it is preferable that a boiling point be low in order to rapidly evaporate the volatile solvent, but when a boiling point is extremely low, the polymer with a fluorocarbon chain will solidify at the tip of the supply head, making it impossible to perform application stably. The boiling point is preferably 50° C. to 140° C., more preferably 60° C. to 100° C. For example, Novec 7200, Novec 7300, and the like manufactured by 3M Company may be used, but the present invention is not particularly limited thereto. Alternatively, these materials may be used in combination.

When the above-described method is performed, there is no residual of the liquid-repellent material on the outer peripheral edge of the mesa portion 11a, which is also the imprint surface, and the liquid-repellent layer 14 can be formed up to the end of the side wall, which contributes most to suppressing oozing, toward the pattern surface on the side wall forming the liquid-repellent layer 14. Thereby, oozing due to the liquid-repellent layer can be effectively suppressed.

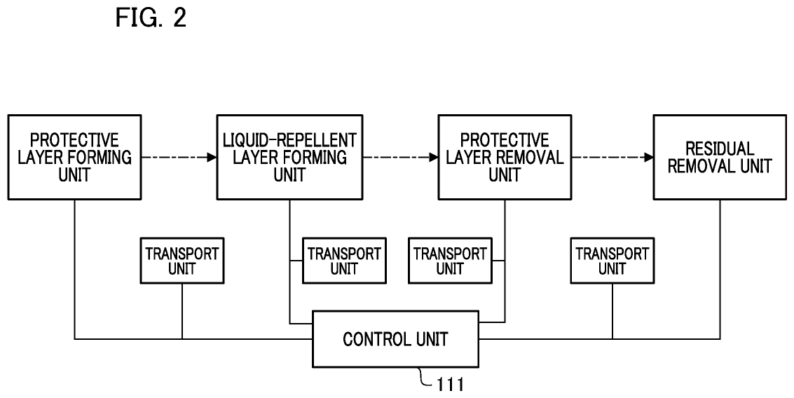

FIG. 2 is a diagram showing an example of a configuration of a removal apparatus (cleaning apparatus) that removes (cleans) residuals of the mold 11 in the present embodiment. The removal apparatus in the present embodiment functions as an apparatus that removes (cleans) residuals of a liquid-repellent material by forming a protective layer, forming the liquid-repellent layer 14 on the mold 11, and dissolving the liquid-repellent layer 14 of the mold 11 by using a solvent.

The removal apparatus in the present embodiment shown in FIG. 2 includes a protective layer forming unit (first forming unit), a liquid-repellent layer forming unit (second forming unit), a protective layer removal unit (second removal unit), a residual removal unit (first removal unit), a transport unit, and a control unit 111. The units are connected to each other by a transport unit that transports an imprint mold. Further, the control unit 111 controls operation contents, operation timings, and the like of the units and the transport unit.

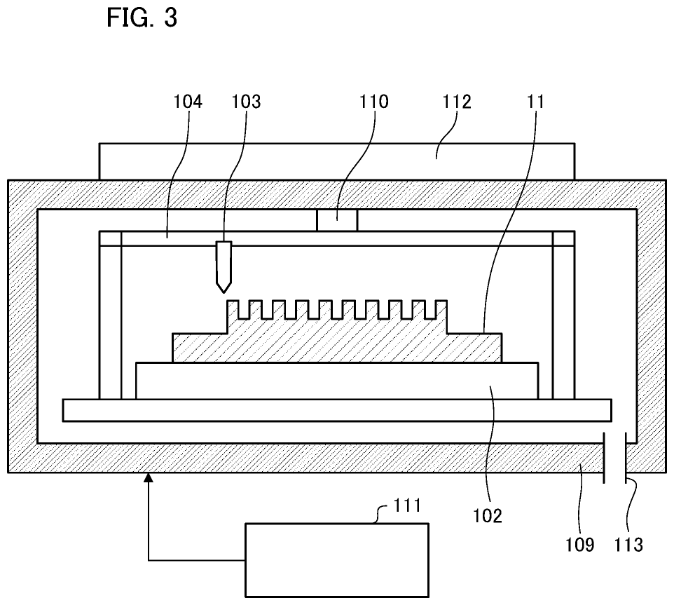

FIG. 3 is a schematic diagram of the protective layer forming unit according to the present embodiment. The protective layer forming unit is a unit that forms a protective layer on the mold 11 by using a liquid protective material to prevent the liquid-repellent layer 14 from being formed on the imprint surface. As will be described later, the protective layer forming unit forms the protective layer on at least the outer peripheral portion of the concavo-convex pattern 11b of the mold 11. The protective layer forming unit includes a stage (mold holding unit, moving mechanism) 102, a supply head 103, a moving mechanism 104, a processing chamber 109, and an imaging unit 110.

The stage 102 functions as a mold holding unit on which the unprocessed mold 11 is disposed and which makes the mold 11 movable in an X-axis direction, a Y-axis direction, and a Z-axis direction while holding the mold 11.

The supply head 103 is a dispenser that ejects a liquid protective material. The supply head 103 can accommodate the liquid protective material supplied from a tank or the like outside the processing chamber 109. Then, the supply head 103 ejects the accommodated liquid protective material toward the unprocessed mold 11 on the stage 102 at a predetermined timing. The supply head 103 is electrically connected to the control unit 111, and its driving is controlled by the control unit 111.

The moving mechanism 104 holds the supply head 103 and moves the supply head 103 relative to the stage 102 while holding the supply head 103. The moving mechanism includes movable mechanisms that move in the X-axis, Y-axis, and Z-axis directions, and the movable mechanisms move independently. As the moving mechanism 104, for example, a moving mechanism such as a linear motor type moving mechanism, an air stage type moving mechanism, or a feed screw type moving mechanism can be used.

The processing chamber 109 is formed in a box shape to be able to accommodate the supply head 103, the stage 102, the imaging unit 110, the moving mechanism 104, and the like. A filter unit 112 equipped with a filter for removing foreign matter from the air is provided on the upper surface of the processing chamber, and an exhaust port 113 is provided on the lower surface (bottom surface) of the processing chamber 109. Inside the processing chamber 109, air flows from the filter in the filter unit to the exhaust port 113, and the inside of the processing chamber 109 is kept clean by downflow (vertical laminar flow). As the filter, for example, a ULPA filter or a HEPA filter can be used. The mold 11 is processed within the processing chamber 109.

The imaging unit 110 is an imaging unit such as a camera that can image the mold 11 on the stage 102. The imaging unit 110 is attached to the upper surface of the processing chamber 109 to be able to particularly image the convex portion of the mold 11 and its surroundings. The imaging unit 110 is electrically connected to the control unit 111, and transmits a captured image (for example, a planar image of the convex portion of the mold 11) to the control unit 111 and an external unit such as an information processing unit.

The liquid-repellent layer forming unit (second forming unit) is a unit that forms the liquid-repellent layer 14 on at least the mesa side wall (side surface of the convex portion) of the mold 11. When the liquid-repellent layer 14 is formed on the side wall 11d of the mesa portion 11a of the mold 11, the liquid-repellent layer forming unit (second forming unit) in the present embodiment also forms the liquid-repellent layer 14 on a portion of the protective layer. The configuration of the liquid-repellent layer forming unit is not particularly limited, but the configuration differs between a dry method and a wet method.

Here, in the case of the dry method, for example, a chamber, a liquid-repellent material holding unit, and a liquid-repellent material heating unit such as a heater are provided, and the liquid-repellent material heating unit heats a liquid-repellent material to evaporate and gasify the liquid-repellent material, thereby forming the liquid-repellent layer 14 on the mold 11.

Further, in the case of the wet method, for example, a configuration can be the same as that of a protective material application unit. That is, it is possible to adopt a configuration in which a stage, a supply head, a moving mechanism, a processing chamber, and an imaging unit are provided. In this case, a liquid-repellent material is supplied from the supply head and applied to a predetermined region including a mesa side wall of a mold. A liquid-repellent layer is also formed by applying a liquid-repellent material onto the mold 11 to have the same configuration as in FIG. 3.

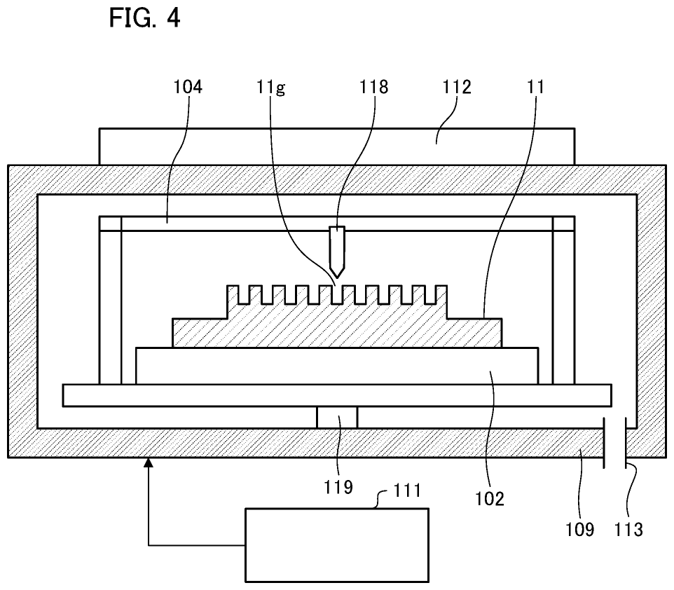

FIG. 4 is a schematic diagram of the protective layer removal unit according to the present embodiment. The protective layer removal unit (second removal unit) is a unit that removes the protective layer formed on the mold 11 by dissolving the protective layer with a protective layer removal material capable of dissolving the protective layer. By dissolving the protective layer by the protective layer removal unit, the protective layer and the liquid-repellent layer 14 formed on a portion of the protective layer can also be removed. The protective layer removal unit (second removal unit) includes a stage (mold holding unit, moving mechanism) 102, a moving mechanism 104, a processing chamber 109, a supply head 118, and a rotation stage 119.

The mold 11 in which the protective layer and the liquid-repellent layer 14 are formed is disposed on the stage 102. Further, the stage 102 functions as a mold holding unit that makes the mold 11 movable in the X-axis direction, the Y-axis direction, and the Z-axis direction while holding the mold 11.

The moving mechanism 104 holds the supply head 118 and moves the supply head 118 relative to the stage 102 while holding the supply head 118. The moving mechanism includes movable mechanisms that move in the X-axis, Y-axis, and Z-axis directions, and the movable mechanisms move independently. As the moving mechanism 104, for example, a moving mechanism such as a linear motor type moving mechanism, an air stage type moving mechanism, or a feed screw type moving mechanism can be used.

The processing chamber 109 is formed in a box shape to be able to accommodate the supply head 118, the stage 102, the moving mechanism 104, and the like. A filter unit 112 equipped with a filter for removing foreign matter from the air is provided on the upper surface of the processing chamber, and an exhaust port 113 is provided on the lower surface (bottom surface) of the processing chamber 109. Inside the processing chamber 109, air flows from the filter in the filter unit to the exhaust port 113, and the inside of the processing chamber 109 is kept clean by downflow (vertical laminar flow). As the filter, for example, a ULPA filter or a HEPA filter can be used. The mold 11 is processed within the processing chamber 109.

The supply head 118 is a dispenser that ejects a protective layer removal material. The supply head 118 can accommodate a liquid removal material supplied from a tank or the like outside the processing chamber 109. Then, the supply head 118 ejects the contained liquid protective material toward the mold 11 on the stage 102 at a predetermined timing. The supply head 118 is electrically connected to the control unit 111, and its driving is controlled by the control unit 111.

The rotation stage 119 is a rotation mechanism that rotates the mold 11 around the Z-axis while holding the mold 11 by vacuum suction or the like.

The removal of the protective layer in the present embodiment is performed using a configuration in which the supply head 118 and the rotation stage 119 are combined. Specifically, the mold 11 on which the liquid-repellent layer is formed is installed on the rotation state 119 so that the rotation center thereof is aligned with the rotation stage 119. At this time, the mold 11 is held on the rotation stage 119 by vacuum suction or the like. After the mold 11 is held, the mold 11 also rotates in association with the rotation of the rotation stage 119. At this time, it is preferable that the rotation stage 119 be rotated at low speed.

Next, the supply head 118 is moved to an upper part of a central part on an imprint surface 11g by the moving mechanism 104 while maintaining the supply head 118 at a predetermined height, and then the protective layer removal material is ejected (applied, supplied) from the supply head 118 to the mold 11. The protective layer removal material is ejected to the central part or the vicinity of the central part of the imprint surface 11g and spreads toward the outer peripheral portion due to the centrifugal force of rotation. Thereby, it is possible to make the dissolved protective layer (protective material) flow out of the mold 11 while dissolving the components of the protective layer. Then, the protective layer is dissolved and removed, and thus a portion of the liquid-repellent layer 14 formed on the protective layer is also removed from the imprint surface 11g. By continuously ejecting the protective layer removal material, all of the components of the protective layer are dissolved in the protective layer removal material. After the protective layer (also including the liquid-repellent layer formed on the protective layer) is removed from the imprint surface 11g, the ejection of the protective layer removal material is stopped, and the surface of the mold 11 is dried. Further, the rotation of the rotation stage 119 is also stopped.

In addition, when the protective layer is removed, a so-called spin method in which the protective layer removal material is supplied from the supply head 118 as described above, and the protective material is dissolved and removed while rotating the mold 11 on the rotation stage 119 may be used. However, a method of removing the protective layer is not limited to the spin method. For example, the protective layer removal unit may include an immersion mechanism in which a container is filled with the protective layer removal material. Then, a so-called immersion method in which the mold 11 is repeatedly immersed in the immersion mechanism filled with the protective layer removal material and is pulled up a plurality of times to dissolve the protective material in the protective layer removal material and remove it may be used.

The residual removal unit (first removal unit) is a unit that removes the residuals from the mold 11 by dissolving the residuals using a predetermined solvent (solvent for the liquid-repellent material) that can dissolve the residuals of the liquid-repellent layer. The configuration of the residual removal unit is not particularly limited. For example, the residual removal unit may include a supply head that supplies a solvent for the liquid-repellent material as shown in FIGS. 3 and 4, and a rotation mechanism that rotates the mold 11. The imprint mold is rotated by the rotation mechanism while supplying the solvent for the liquid-repellent material from the supply head and dissolving the residuals of the liquid-repellent material, and thus it is possible to dissolve the residuals remaining around the liquid-repellent layer in the solvent for the liquid-repellent material and remove it (spin method). Similarly to the method in the protective layer removal unit, the removal of the residuals is performed by ejecting the solvent onto the imprint surface on the mold 11, dissolving the residuals by the centrifugal force of rotation, making the residuals flow out of the mold.

For example, an immersion mechanism in which a container is filled with a solvent for a liquid-repellent material may be provided. Then, the mold 11 is repeatedly immersed in the immersion mechanism filled with the solvent for the liquid-repellent material and pulled up a plurality of times, and thus the residuals remaining around the liquid-repellent layer 14 can be dissolved in the solvent for the liquid-repellent material and removed (immersion method).

The transport unit transports the mold 11 between the units while holding the mold 11. As the transport unit, a movable stage may be used, or a multi-axis robot may be used.

The control unit 111 includes a CPU, a memory (storage unit), and the like, is constituted by at least one computer, and is electrically connected to each component of the removal apparatus via a line. Further, the control unit 111 comprehensively controls operation adjustment and the like of the components in the entire removal apparatus, such as operation contents and operation timings of the units and the transport unit, in accordance with programs stored in the memory. Further, the control unit 111 may be configured integrally with other parts of the removal apparatus (in a common housing). Further, the control unit 11 may be configured separately from other parts of the removal apparatus (in a separate housing), or may be installed at a location separate from the removal apparatus and controlled remotely. Further, the CPU may be an MPU. Further, the memory stores, for example, various operation contents, operation timings, and the like.

In the present embodiment, a configuration in which the protective layer forming unit, the liquid-repellent layer forming unit, the protective layer removal unit, and the residual removal unit are each disposed independently in a processing unit is described as shown in FIG. 2. However, mechanisms of a plurality of units may be integrated into one unit. For example, a configuration may be adopted in which one unit includes a plurality of material supply heads so that the formation of the protective layer and the formation of the liquid-repellent layer are performed within one unit.

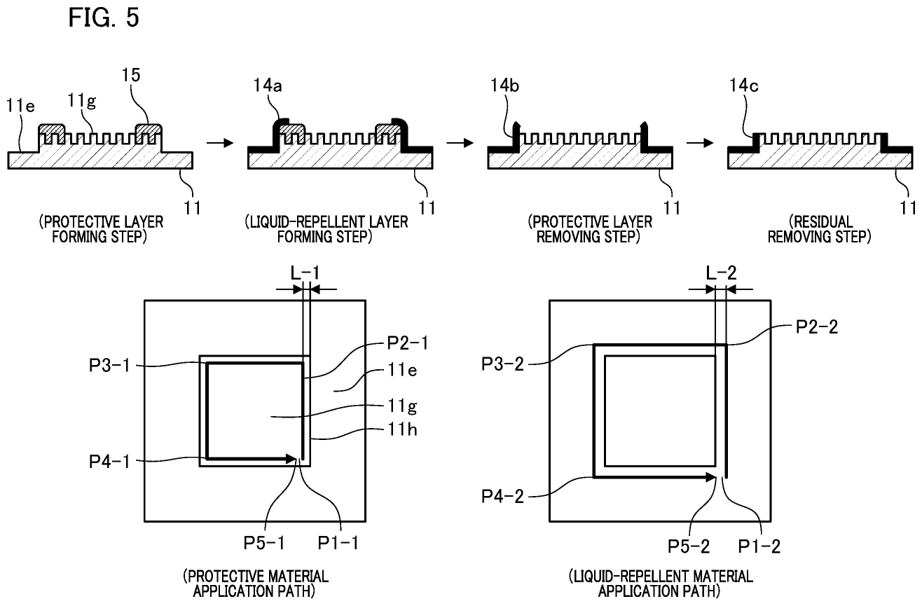

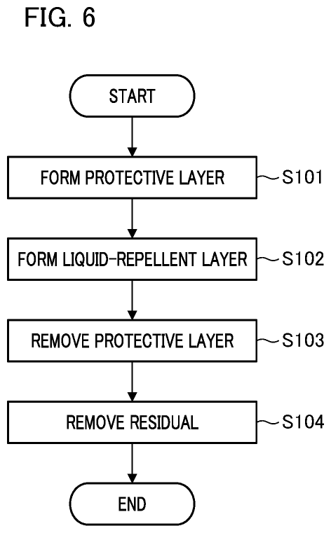

FIG. 5 is a diagram for describing each processing stage of a removing step (cleaning step) for removing residuals according to the present embodiment. FIG. 6 is a flowchart showing residual removal processing in the present embodiment. Reference numeral 15 shown in FIG. 5 denotes a protective layer (hereinafter referred to as a protective layer 15). Further, reference numeral 14a denotes a liquid-repellent layer formed on a mesa side wall portion and a portion of the protective layer 15 before the protective layer is removed (hereinafter referred to as a liquid-repellent layer 14a). Further, reference numeral 14b denotes a liquid-repellent layer after the protective layer 15 is removed (hereinafter referred to as a liquid-repellent layer 14b). In addition, reference numeral 14c denotes a liquid-repellent layer after residuals are removed (hereinafter referred to as a liquid-repellent layer 14c). In FIG. 5, the protective layer and the liquid-repellent layer at each stage are given reference numbers for clearness of description.

In the present embodiment, as described above, the protective layer 15 is formed at the outer peripheral portion of the imprint surface of the mold 11, and the liquid-repellent layer 14a is formed on the mesa side wall. Thereafter, the protective layer 15 is removed, and unnecessary residuals are removed using a removing method for finally removing the residuals, thereby forming the liquid-repellent layer 14c as shown in FIG. 5. A detailed description will be given below with reference to FIGS. 5 and 6. The following processes are realized by causing the control unit 111 of the processing unit to execute the programs stored in the memory. Further, “S” is added to the beginning of each step, and thus the notation of the step is omitted.

First, in S101, the control unit 111 controls the protective layer forming unit to apply a liquid protective material to the outer peripheral portion of the imprint surface on the mold 11 from the supply head 103, thereby forming the protective layer 15 on the mold 11 as shown in FIG. 5 (first forming step). When the protective layer 15 that prevents a liquid-repellent layer from being formed is formed, the protective layer 15 is formed on at least the outer peripheral portion of the concavo-convex pattern in the mold 11. Here, the supply head 103 is moved by the moving mechanism 104 along application paths P1-1 to P5-1 on the imprint surface 11g as shown in FIG. 5 while maintaining a predetermined height, and continuously supplies a protective material to the imprint surface 11g on the mold 11.

The application paths P1-1 to P5-1 are separated from the outer peripheral portion of the imprint surface 11g by a predetermined distance L-1 (for example, 0.2 mm). P1-1 is an ejection start position, and P5-1 is an ejection stop position. The protective material is applied only to the outer peripheral portion of the imprint surface 11g through this application path. Further, the liquid protective material applied on this application path gets wet and spreads on the imprint surface due to wet-spreading due to surface energy and reaches an outer peripheral edge 11h of the imprint surface. By performing the first forming step in this manner, the protective layer 15 can be formed on the outer peripheral portion of the mold 11.

Next, in S102, the control unit 111 controls the liquid-repellent layer forming unit to apply a liquid-repellent material to the upper surface 11e on the mold 11 from the supply head, thereby forming the liquid-repellent layer 14a as shown in FIG. 5 (second forming step). When the liquid-repellent layer 14a is formed, the liquid-repellent layer 14a is formed on at least the side surface of the convex portion of the mold 11. The application paths P1-2 to P5-2 move along the outer periphery of the imprint surface 11g to the upper surface 11e in the order of P1-2, P2-2, P3-2, P4-2, and P5-2. The application path is separated from the imprint surface 11g by a predetermined distance L-2 (for example, 1 mm). In the present embodiment, P1-2 is an ejection start position, and P5-2 is an ejection stop position.

A region where the liquid-repellent material is applied through this application path has, for example, a frame shape surrounding the imprint surface 11g. The liquid-repellent material applied through this application path spreads due to its wettability and reaches the side wall 11d of the mesa portion 11a, and then passes over the side wall 11d of the mesa portion 11a and reaches the protective layer 15 formed on the outer periphery of the imprint surface 11g. By applying the liquid-repellent material in this manner, the liquid-repellent material can be applied to the side wall 11d and the upper surface 11e around the side wall 11d.

Thereafter, when a volatile solvent contained in the liquid-repellent material evaporates and dries, the liquid-repellent layer 14a is formed on the side wall 11d of the mesa portion 11a and a portion of the protective layer 15. In this manner, the second forming step is performed after the first forming step, and thus the liquid-repellent material does not reach the imprint surface on which the protective layer 15 is not formed. For this reason, the liquid-repellent layer can be formed on at least the side surface of the convex portion of the mold 11 without forming the liquid-repellent layer 14a on the imprint surface 11g.

Next, in S103, the control unit 111 controls the protective layer removal unit to supply the protective layer removal material capable of dissolving the protective layer 15 from the supply head 118 to the mold 11 to remove the protective layer 15 formed on the mold 11 (second removing step). When the protective layer 15 is removed, first, the mold 11 having the liquid-repellent layer 14a formed on the rotation stage 119 is installed such that the rotation center thereof is aligned with the rotation stage 119. At this time, after the mold 11 is installed, the mold 11 is held on the rotation stage 119 by a method such as vacuum suction. After the mold 11 is held, the rotation stage 119 and the mold 11 are rotated at low speed. After the mold 11 is rotated at low speed, the supply head 118 is moved to an upper part of a central part on the imprint surface 11g by the moving mechanism 104 while maintaining the supply head 118 at a predetermined height, and then the protective layer removal material is ejected onto the mold 11 from the supply head 118.

The protective layer removal material is ejected to the central part of the imprint surface 11g, spreads toward the outer peripheral portion due to the centrifugal force of rotation, dissolves the components of the protective layer 15, and flows out of the mold 11. When the protective layer 15 is dissolved and removed, a portion of the liquid-repellent layer 14a formed on the protective layer 15 is also removed. When all of the components of the protective layer 15 are dissolved in the protective layer removal material and removed from the imprint surface 11g by continuously ejecting the protective layer removal material, the ejection of the protective layer removal material is stopped, and the surface of the mold 11 is dried. The second removing step is performed after the second forming step in this manner, and thus the liquid-repellent layer 14b as shown in FIG. 5 can be formed.

Finally, in S104, the control unit 111 controls the residual removal unit to remove the residuals in the mold 11 on which the liquid-repellent layer 14b, which is a liquid-repellent layer after the protective layer 15 is removed, is formed (first removing step). In the removal of the residuals, the liquid-repellent layer 14b is dissolved using a predetermined solvent to remove the residuals on the outer peripheral edge of the mesa portion 11a. Further, the removal of the residuals is performed using a configuration in which the supply head 118 and the rotation stage 119 shown in FIG. 4 are combined. The mold 11 on which the liquid-repellent layer 14b is formed is installed on the rotation stage 119 so that the rotation center thereof is aligned with the rotation stage 119.

At this time, after the mold 11 is installed, the mold 11 is fixed to the rotation stage 119 by a method such as vacuum suction, and then the rotation stage 119 and the mold 11 are rotated at low speed. The supply head 118 is moved to an upper part of the central part on the imprint surface 11g by the moving mechanism 104 while maintaining the supply head 118 at a predetermined height, and then the solvent for the liquid-repellent material is ejected from the supply head 118 to the mold 11. The solvent for the liquid-repellent material is ejected to the central part of the imprint surface 11g, spreads toward the outer peripheral portion due to the centrifugal force of rotation, dissolves the residuals, and flows out of the mold 11 and is thus removed. When the solvent for the liquid-repellent material is continuously ejected, and all unnecessary residuals are dissolved in the solvent for the liquid-repellent material and removed from the imprint surface 11g, the ejection of the solvent for the liquid-repellent material is stopped. Thereby, it is possible to form the liquid-repellent layer 14c from which the unnecessary residuals are removed. Thereafter, the surface of the mold 11 is dried. In this manner, the first removing step is performed after the second removing step, and thus the liquid-repellent layer 14c from which the unnecessary residuals are removed as shown in FIG. 5 can be formed on at least the side wall 11d of the mesa portion 11a.

By the above-described removing method, it is possible to obtain a mold (manufacture a mold) in which the protective material and unnecessary residuals on the imprint surface are removed, and the liquid-repellent layer 14c, which is a liquid-repellent layer from which residuals are removed only on the mesa side wall, is formed.

As described above, in the removing method using the removal apparatus in Embodiment 1, it is possible to form a liquid-repellent layer in which only the mesa side wall is formed with high precision, without making the entire region of the concavo-convex pattern surface of the mold 11 liquid-repellent. Then, it is possible to remove residuals generated on at least the side surfaces of the convex portions of the mold with high precision.

In the present embodiment, the liquid-repellent layer is formed after the protective layer is formed on the patterned surface of the mold 11, but a light-shielding layer for shielding exposure light may be formed on the side surface of the mesa portion 11a of the mold 11. When the light-shielding layer is formed, the method in the present embodiment of forming a protective layer in advance is also effective.

In addition, since the protective layer formed over the entire imprint surface of the mold 11 can protect the imprint surface from dust and contamination other than the liquid-repellent material, the present invention is not limited to the mold 11 for imprinting, and the protective layer also functions as a contamination protection layer when the mold 11 is transported.

The removal apparatus described above can be introduced as an apparatus that makes the mesa side wall of the mold 11 liquid-repellent and removes residuals by including a transport mechanism, a loading unit, an unloading unit, and the like

In the present embodiment, the protective layer is formed by the protective layer forming unit. Here, for example, after the concavo-convex pattern 11b is protected using a light-shielding plate having a predetermined shape, the liquid-repellent layer may be formed by the liquid-repellent layer forming unit, and residuals generated at the end of the mesa portion 11a may be removed by the residual removal unit. At this time, the light-shielding plate is disposed to face the concavo-convex pattern 11b and to be away from the concavo-convex pattern 11b. Further, for example, the concavo-convex pattern 11b is protected by bringing a predetermined cushioning material into contact with the concavo-convex pattern 11b and disposing a mold substrate on the cushioning material. Thereafter, the liquid-repellent layer 14 may be formed by the liquid-repellent layer forming unit, and residuals generated at the end of the mesa portion 11a may be removed by the residual removal unit. The cushioning material is, for example, a liquid such as water, alcohol, or thinner, or a gel-like member. Furthermore, the mold substrate is formed of, for example, quartz. Further, for example, the liquid-repellent layer 14 may be formed by the liquid-repellent layer forming unit in a state where the concavo-convex pattern 11b is pressed against the curable composition 13, and residuals generated at the end of the mesa portion 11a, and the like may be removed by the residual removal unit. When such a removing method is adopted, the protective layer removal unit can be eliminated from the configuration of the removal apparatus. By eliminating the protective layer removal unit, the size of the entire removal apparatus can be reduced.

Further, the mold 11 in which the liquid-repellent layer 14 is formed on the side wall 11d of the mesa portion 11a may be prepared using the outside of the removal apparatus in the present embodiment, that is, an external apparatus or the like, and residuals generated at the end of the mesa portion 11a, and the like may be removed using the residual removal unit. In such a case, the removal apparatus may be constituted by only the residual removal unit. That is, the protective layer forming unit, the liquid-repellent layer forming unit, and the protective layer removal unit can be eliminated from the configuration of the removal apparatus, and the size of the entire removal apparatus can be reduced. Further, a period of time required to remove residuals can be shortened.

### EXAMPLE 1

Hereinafter, an experimental example in which the side surface of the mold 11 (the side wall 11d of the mesa portion 11a) was made liquid-repellent using the removing method of the present embodiment will be described. As conditions for making the side surface of the mold 11 liquid-repellent using the method according to the present embodiment, glycerin was used as the protective material, and water was used as the protective layer removal material. In addition, a polymer having a perfluoropolyether group, which is carbon chain 2, in the main chain and dissolved in a volatile solvent at a solid content concentration of 0.09 wt % was used for the liquid-repellent material, and Novec 7200 manufactured by 3M Company was used for a cleaning solvent for the liquid-repellent material. Further, a cleaning time using the cleaning solvent was set to 5 seconds.

In order to evaluate the liquid repellency after the liquid repellency processing is performed, the presence or absence of residuals of the liquid-repellent material on the imprint surface was confirmed using an observation mechanism of an optical microscope. Further, cross-sectional exposure processing using FIB-SEM and SEM observation were performed on the formed liquid-repellent layer, and a film thickness was measured. Furthermore, in order to evaluate the liquid repellency, a curable composition before curing was dropped onto the side wall of the mold 11 after the liquid-repellent layer was formed, and the contact angle thereof was measured. Regarding determination for the contact angle, the liquid repellency was O in the case of 70° to 100°, the liquid repellency was Δ (triangle) in the case of 65° to 69°, and the liquid repellency was × (cross) in the case of 68° or less and 101° or more.

As the film thickness measurement and evaluation results for the liquid-repellent layer in Example 1, no residuals remained, the film thickness was 35 nm, and the liquid repellency was ∘ (circle). Thus, under the conditions in Example 1, satisfactory results were obtained for the removal of residuals and the film thickness after the removal of the residuals.

### EXAMPLE 2

In Example 2, the side surface of the mold 11 was made liquid-repellent by changing the cleaning time to 30 seconds in the same manner as in Example 1. In Example 2, the conditions were the same as in Example 1 except that the cleaning time was changed to 30 seconds. Here, when the film thickness of the liquid-repellent layer was measured and the liquid repellency was evaluated in the same manner as in Example 1, no residuals remained, the film thickness was 30 nm, and the liquid repellency was ∘ (circle). Thus, under the conditions in Example 2, satisfactory results were obtained for the removal of residuals and the film thickness after the removal of the residuals.

### EXAMPLE 3

In Example 3, the side surface of the mold 11 was made liquid-repellent by changing the cleaning time to 15 minutes in the same manner as in Example 1. In Example 3, the conditions were the same as in Example 1 except that the cleaning time was changed to 15 minutes. Here, when the film thickness of the liquid-repellent layer was measured and the liquid repellency was evaluated in the same manner as in Example 1, no residuals remained, the film thickness was 21 nm, and the liquid repellency was ∘ (circle). Thus, under the conditions in Example 3, satisfactory results were obtained for the removal of residuals and the film thickness after the removal of the residuals.

### Example 4

In Example 4, the side surface of the mold 11 was made liquid-repellent by changing the cleaning solvent to Novec 7300 manufactured by 3M Company in the same manner as in Example 1. In Example 4, the conditions were the same as in Example 1 except that the cleaning solvent was changed to Novec 7300 manufactured by 3M Company. Here, when the film thickness of the liquid-repellent layer was measured and the liquid repellency was evaluated in the same manner as in Example 1, no residuals remained, the film thickness was 38 nm, and the liquid repellency was ∘ (circle). Thus, under the conditions in Example 4, satisfactory results were obtained for the removal of residuals and the film thickness after the removal of the residuals.

### EXAMPLE 5

In Example 5, the side surface of the mold 11 was made liquid-repellent by changing the cleaning time to 30 seconds in the same manner as in Example 4. In Example 5, the conditions were the same as in Example 4 except that the cleaning time was changed to 30 seconds. Here, when the film thickness of the liquid-repellent layer was measured and the liquid repellency was evaluated in the same manner as in Example 1, no residuals remained, the film thickness was 35 nm, and the liquid repellency was ∘ (circle). Thus, under the conditions in Example 5, satisfactory results were obtained for the removal of residuals and the film thickness after the removal of the residuals.

### EXAMPLE 6

In Example 6, the side surface of the mold 11 was made liquid-repellent by changing the cleaning solvent to acetone in the same manner as in Example 1. In Example 6, the conditions were the same as in Example 1 except that the cleaning solvent was changed to acetone. Here, when the film thickness of the liquid-repellent layer was measured and the liquid repellency was evaluated in the same manner as in Example 1, no residuals remained, the film thickness was 11 nm, and the liquid repellency was Δ. Thus, as the results in Example 6, although the film thickness of the liquid-repellent layer was smaller than those in Examples 1 to 5, necessary liquid repellency was maintained, and the residuals were removed, and thus results with no problem were obtained.

### COMPARATIVE EXAMPLE 1

In Comparative Example 1, the side surface of the mold 11 was made liquid-repellent by changing the cleaning solvent to water in the same manner as in Example 1. In Comparative Example 1, the conditions were the same as in Example 1 except that the cleaning solvent was changed to water. Here, when the film thickness of the liquid-repellent layer was measured and the liquid repellency was evaluated in the same manner as in Example 1, residuals remained on a portion of the imprint surface. The film thickness was 80 nm, and the liquid repellency was ∘ (circle). Thus, as the results in Comparative Example 1, although a sufficient film thickness of the liquid-repellent layer remained, a result that the residuals could not be removed was obtained.

### COMPARATIVE EXAMPLE 2

In Comparative Example 2, the side surface of the mold 11 was made liquid-repellent by changing the cleaning solvent to hexane in the same manner as in Example 1. In Comparative Example 2, the conditions were the same as in Example 1 except that the cleaning solvent was changed to hexane. Here, when the film thickness of the liquid-repellent layer was measured and the liquid repellency was evaluated in the same manner as in Example 1, residuals remained on a portion of the imprint surface. The film thickness was 71 nm, and the liquid repellency was ∘ (circle). Thus, as the results in Comparative Example 1, although a sufficient film thickness of the liquid-repellent layer remained, a result that the residuals could not be removed was obtained.

### COMPARATIVE EXAMPLE 3

In Comparative Example 3, the side surface of the mold 11 was made liquid-repellent by changing the cleaning solvent to ethanol in the same manner as in Example 1. In Comparative Example 3, the conditions were the same as in Example 1 except that the cleaning solvent was changed to ethanol. Here, when the film thickness of the liquid-repellent layer was measured and the liquid repellency was evaluated in the same manner as in Example 1, residuals remained on a portion of the imprint surface. The film thickness was 69 nm, and the liquid repellency was ∘ (circle). Thus, as the results in Comparative Example 1, although a sufficient film thickness of the liquid-repellent layer remained, a result that the residuals could not be removed was obtained.

As described above, compared to the results in Examples 1 to 6, in each of Comparative Examples 1 to 3, a sufficient film thickness of the liquid-repellent layer remained, but a result that the residuals were not removed was obtained. Here, Table 1 below shows the cleaning conditions and the evaluations in Examples 1 to 6 and Comparative Examples 1 to 3.

TABLE 1

| | | | | Evaluation | | | |
|---|---|---|---|---|---|---|---|
| | | | | | | | Liquid |
| | Cleaning Condition | | | Film | | | Repel- |
| | Solvent | Time | | Thickness | | Residue | lency |
| Example 1 | novec 7200 | 5 | seconds | 35 | nm | ∘ | ∘ |
| Example 2 | novec 7200 | 30 | seconds | 30 | nm | ∘ | ∘ |
| Example 3 | novec 7200 | 15 | minutes | 18 | nm | ∘ | ∘ |
| Example 4 | novec 7300 | 5 | seconds | 38 | nm | ∘ | ∘ |
| Example 5 | novec 7300 | 30 | seconds | 35 | nm | ∘ | ∘ |
| Example 6 | acetone | 5 | seconds | 11 | nm | ∘ | Δ |
| Comparative | water | 5 | seconds | 80 | nm | x | ∘ |
| Example 1 | | | | | | | |
| Comparative | hexane | 5 | seconds | 71 | nm | x | ∘ |
| Example 2 | | | | | | | |
| Comparative | ethanol | 5 | seconds | 69 | nm | x | ∘ |
| Example 3 | | | | | | | |

The processing apparatus in the present embodiment described above can be mounted in an imprint apparatus. The imprint apparatus is an apparatus that brings an imprint material disposed in a pattern formation region on a substrate into contact with a concavo-convex pattern of a mold and cures the imprint material, thereby forming a pattern formed of the cured imprint material on the substrate. Then, the imprint apparatus that forms a pattern formed of a cured material in a plurality of pattern formation regions is used, for example, in the manufacture of devices such as semiconductor devices. In the present embodiment, the imprint apparatus adopts a photocuring method.

As the imprint material, a curable composition (may be referred to as an uncured resin) that is cured by being given curing energy is used. As energy for curing, electromagnetic waves, heat, and the like can be used. The electromagnetic wave may be, for example, light whose wavelength is selected from a range of 10 nm or more and 1 mm or less, such as infrared rays, visible light, and ultraviolet rays. The curable composition may be a composition that is cured by irradiation with light or by heating.

Among these, a photocurable composition that is cured by irradiation with light contains at least a polymerizable compound and a photopolymerization initiator, and may further contain a non-polymerizable compound or a solvent as necessary. The non-polymerizable compound is at least one selected from the group of a sensitizer, a hydrogen donor, an internal mold release agent, a surfactant, an antioxidant, a polymer component, and the like. The imprint material can be disposed on the substrate in the form of droplets, or in the form of islands or films formed by connecting a plurality of droplets.

The imprint apparatus may include a mold holding unit, a structure, an irradiation unit, a substrate drive mechanism, a base surface plate, a substrate holding unit (substrate stage), a dispenser (ejection device), a mold drive mechanism, an imaging unit, a control unit, and the like.

The mold holding unit includes a drive mechanism (moving unit) that moves the mold while holding the mold. The mold holding unit can hold the mold by attracting an outer peripheral region of the surface of the mold that is irradiated with irradiation light using a vacuum suction force or an electrostatic force. The structure supports a die drive mechanism.

The irradiation unit (curing unit) cures the imprint material on the substrate by irradiating the imprint material with irradiation light such as ultraviolet rays through a prism. The irradiation unit may include an exposure light source, an optical element that adjusts the irradiation light emitted from the exposure light source to light suitable for imprinting, and a light-shielding plate (masking blade) that limits an irradiation region (irradiation range) of the irradiation light emitted from the exposure light source.

The substrate holding unit includes a substrate drive mechanism (moving unit) that allows the substrate to be moved in each axis direction while holding the substrate. The base surface plate supports the substrate holding unit and the substrate drive mechanism. The substrate drive mechanism and the mold drive mechanism are configured as relative drive mechanisms that drive at least one of the substrate and the mold so that the relative positions of the substrate and the mold are adjusted. The adjustment of the relative positions by the relative drive mechanisms (the substrate drive mechanism and the die drive mechanism) includes contact between the imprint material on the substrate and the concavo-convex pattern of the mold, and driving for separation of the cured imprint material and the mold.

The substrate drive mechanism may be configured to drive the substrate along a plurality of axes (for example, three axes: an X-axis, a Y-axis, and a θZ-axis, preferably six axes: the X-axis, the Y-axis, a Z-axis, a θX-axis, a θY-axis, and the θZ-axis). The die drive mechanism may be configured to drive the mold along a plurality of axes (for example, three axes: the Z-axis, the θX-axis, and the θY-axis, preferably six axes: the X-axis, the Y-axis, the Z-axis, the θX-axis, the θY-axis, and the θZ-axis).

The dispenser (supply unit) disposes (supplies) the imprint material in the pattern formation region (imprint region) on the substrate. The dispenser can dispose the imprint material at a target position on the substrate, for example, by ejecting the imprint material from the dispenser while scanning the substrate using the substrate drive mechanism.

The number of imaging units configured is one or two or more, and the imaging unit measures relative positions of an alignment mark of the pattern formation region of the substrate and an alignment mark of the mold by capturing an image formed by both the alignment marks. The imaging unit may be configured to perform the above-described imaging through a prism.

The control unit includes a CPU, a memory (storage unit), and the like, is constituted by at least one computer, and is connected to each component of the imprint apparatus via a line. Further, the control unit comprehensively controls operation adjustment and the like of the components in the entire imprint apparatus in accordance with programs stored in the memory. That is, the control unit controls the irradiation unit, the substrate drive mechanism, the dispenser, the die drive mechanism, the imaging unit, and the like. The control unit may be configured integrally with other parts of the imprint apparatus (in a common housing). Further, the control unit may be configured separately from other parts of the imprint apparatus (in a separate housing), or may be installed at a location separate from the imprint apparatus and controlled remotely.

Further, the control unit may be constituted by a programmable logic device (PLD) such as a field programmable gate array (FPGA). Alternatively, the control unit may be constituted by an application specific integrated circuit (ASIC). Alternatively, the control unit may be constituted by a general-purpose computer in which programs are installed, or a combination of all or some of these.

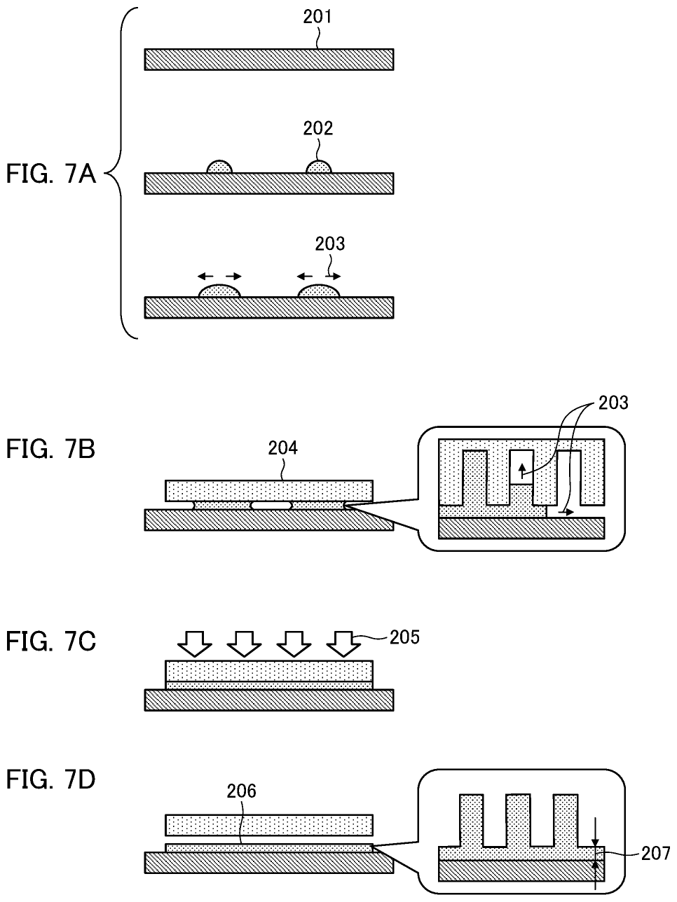

The imprint processing, which is processing for forming a pattern using the imprint material on the pattern formation region of the substrate and is performed by the imprint apparatus of the present embodiment, may include a lamination step, a contact step, a light irradiation step, and a mold release step. This imprint processing is performed on one pattern formation region in the order of the lamination step, the contact step, the light irradiation step, and the mold release step. The imprint processing may include an alignment step of aligning the substrate and the mold between the contact step and the light irradiation step. The steps of the imprint processing according to the present embodiment will be described below with reference to FIG. 7. FIG. 7 is a schematic cross-sectional view showing imprint processing performed by the imprint apparatus. FIG. 7A is a schematic cross-sectional view showing an example of the lamination step. FIG. 7B is a schematic cross-sectional view showing an example of the contact step. FIG. 7C is a schematic cross-sectional view showing an example of the light irradiation step. FIG. 7D is a schematic cross-sectional view showing an example of the mold release step.

It is preferable that a cured film of the curable composition obtained by the imprint method according to the present embodiment have a pattern with a size of 1 nm or more and 10 mm or less. In general, a pattern forming technique for producing a film having a nano-sized (1 nm or more and 1000 nm or less) pattern (concavo-convex structure) using light is referred to as an optical nanoimprint method. The imprint method according to the present embodiment uses the optical nanoimprint method. Each step will be explained below. Each processing in each step below is realized by causing the control unit of the imprint apparatus to execute programs stored in the memory. The processing may be realized by the control unit 111 of the processing apparatus.

As an example of the lamination step illustrated in FIG. 7A, droplets of a curable composition 202 are discretely dropped and arranged on a substrate 201 via a dispenser as shown in FIG. 7. An inkjet method is particularly preferred as an arrangement method. The droplets of the curable composition 202 are densely arranged on the substrate 201 facing a region where concave portions are densely present on a mold 204, and sparsely arranged on the substrate facing a region where concave portions are sparsely present. Thereby, the thickness of a residual film, which will be described later, can be controlled to be uniform regardless of the density of the pattern on the mold 204.

The dropped droplets gradually spread on a substrate surface over time. An arrow 203 shown in the drawing indicates a direction in which the droplets spread.

As another example of the lamination step, the curable composition 202 may be disposed on the substrate 201 using a spin coating method. In this case, the curable composition 202 is continuously disposed on the substrate 201.

The viscosity at 25° C. of a mixture of components of the curable composition 202 according to the present embodiment excluding a solvent is preferably 1 mPa·s or more and less than 40 mPa·s. In addition, the viscosity is more preferably 1 mPa·s or more and less than 20 mPa·s. When the viscosity of the curable composition 202 exceeds 40 mPa·s, it is not possible to perform application using an inkjet method capable of making a residual film thickness uniform by discretely arranging droplets in accordance with the density of a desired pattern, and forming high-precision patterns. In addition, when the viscosity is lower than 1 mPa·s, uneven application may occur due to the composition flowing when applied (arranged), or the composition may flow out from the end of the mold 204 during the contact step to described later, which leads to an undesirable result.

The surface tension of the curable composition 202 according to the present embodiment is preferably 5 mN/m or more and 70 mN/m or less at 23° C. for the composition of components excluding a solvent. Further, the surface tension is more preferably 7 mN/m or more and 50 mN/m or less, and still more preferably 10 mN/m or more and 40 mN/m or less.

Here, as the surface tension becomes higher, for example, 5 mN/m or more, a capillary force acts more strongly, and thus, when the curable composition 202 is brought into contact with the mold 204, filling (spreading and filling) is completed in a short period of time. In addition, when the surface tension is set to 70 mN/m or less, the cured film obtained by curing the curable composition becomes a cured film having surface smoothness.

A contact angle of the curable composition 202 according to the present embodiment with respect to the imprint surface and the substrate surface is preferably 0° or more and 90° or less for the composition of the components excluding the solvent. When the contact angle is larger than 90°, a capillary force acts in a negative direction (in a direction in which a contact interface between the mold and the curable composition is contracted) inside the concavo-convex pattern of the mold 204 and in a gap between the substrate 201 and the mold 204, and filling is not performed. The contact angle is particularly preferably 0° or more and 30° or less. As the contact angle becomes smaller, the capillary force acts more strongly, and thus a filling speed is high.

The substrate 201 on which the curable composition 202 is disposed is a substrate to be processed, and for example, a silicon substrate is used. A layer to be processed may be formed on the substrate 201. Another layer may be formed between the substrate 201 and the layer to be processed. Furthermore, when a quartz substrate is used as the substrate 201, a replica of a quartz imprint mold (mold replica) can be produced.

However, the substrate 201 is not limited to a silicon substrate or a quartz substrate. The substrate 201 can be arbitrarily selected from among those known as substrates for semiconductor devices of such as aluminum, a titanium-tungsten alloy, an aluminum-silicon alloy, an aluminum-copper-silicon alloy, silicon oxide, and silicon nitride.

Adhesion between the surface of the substrate 201 to be used (substrate to be processed) or the layer to be processed and the curable composition 202 is improved by surface treatment such as silane coupling treatment, silazane treatment, and organic thin film formation.

In the contact step, as shown in FIG. 7B, the mold 204 for imprinting having a master pattern for transferring a pattern shape is brought into contact with the curable composition 202 formed in the previous step (lamination step). Thereby, the curable composition 202 is filled into a concave portion of a fine pattern formed on the surface of the mold 204, thereby forming a liquid film that fills the fine pattern of the mold 204. Here, an arrow 203 indicates a direction in which the droplet (curable composition) spreads (fills the concave portion).

It is preferable to use the mold 204 formed of a light-transmitting material in consideration of the next step (light irradiation step). Specifically, as a material forming the mold 204, specifically, glass, quartz, PMMA, an optically transparent resin such as a polycarbonate resin, a transparent metal vapor deposited film, a flexible film such as polydimethylsiloxane, a photocured film, a metal film, and the like are preferable as a base material. However, when an optically transparent resin is used as the material forming the mold 204, it is necessary to select a resin that does not dissolve in the components contained in the curable composition 202. The material forming the mold 204 is particularly preferably quartz because it has a small coefficient of thermal expansion and a small pattern distortion.

It is preferable that the fine pattern formed on the surface of the mold 204 have a pattern height of 4 nm or more and 200 nm or less. As the pattern height becomes lower, a force to peel the mold off from the photocured film of the curable composition in the mold release step, that is, a mold release force, becomes smaller, and the number of old release defects remaining on the mold 204 side due to curable composition pattern being torn off in association with the mold release becomes smaller. Adjacent curable composition patterns may come into contact with each other due to elastic deformation of the curable composition pattern due to impact when the mold is peeled off, and the curable composition patterns may coalesce or be damaged. However, when the pattern height is approximately twice or less than a pattern width (aspect ratio is 2 or less), there is a high possibility that these those problems can be avoided. On the other hand, when the pattern height is excessively low, the processing accuracy of the substrate to be processed is low.

As described above, the present invention also includes a case where a mold having no fine pattern on the imprint surface is used for the purpose of obtaining a flat surface of a curable composition. That is, the processing apparatus in the present embodiment can also be mounted in a flattening apparatus or the like that uses a mold having no fine pattern on an imprint surface.

The mold 204 may undergo surface treatment before the step of bringing the curable composition 202 into contact with the mold 204 in order to improve detachability between the photocured curable composition 202 and the surface of the mold 204. Examples of the surface treatment method include a method of applying a mold release agent to the surface of the mold 204 to form a mold release agent layer. Here, the mold release agent applied onto the surface of the mold 204 includes a silicone mold release agent, a fluorine mold release agent, a hydrocarbon mold release agent, a polyethylene mold release agent, a polypropylene mold release agent, a paraffin mold release agent, a montan mold release agent, a carnauba mold release agent, and the like. For example, a commercially available coating type release agent such as OPTOOL (registered trademark) DSX manufactured by Daikin Chemicals can also be preferably used. In addition, one type of mold release agent may be used alone, or two or more types may be used in combination. Among these, fluorine-based and hydrocarbon-based mold release agents are particularly preferably used.

In the contact step, as illustrated in FIG. 7B, when the mold 204 and the curable composition 202 are brought into contact with each other, pressure applied to the curable composition 202 is not particularly limited. The pressure is preferably 0 MPa or more and 100 MPa or less. Further, the pressure is preferably 0 MPa or more and 50 MPa or less, more preferably 0 MPa or more and 30 MPa or less, and still more preferably 0 MPa or more and 20 MPa or less.

In the contact step, a period of time for which the mold and the curable composition 202 are brought into contact with each other is not particularly limited, but is preferably set to, for example, 0.1 seconds or more and 600 seconds or less. Further, the period of time is preferably 0.1 seconds or more and 3 seconds or less, particularly preferably 0.1 seconds or more and 1 second or less. When the period of time is shorter than 0.1 seconds, spreading and filling are insufficient, and defects referred to as non-filling defects tend to occur frequently.

The contact step can be performed under any of the following conditions, that is, under an air atmosphere, under a reduced-pressure atmosphere, or under an inert gas atmosphere. Here, since it is possible to prevent the influence of oxygen and moisture on a curing reaction, it is preferable to use an inert gas as a reduced-pressure atmosphere or an atmosphere control gas to set an inert gas atmosphere. Specific examples of the inert gas that can be used when performing the contact step under an inert gas atmosphere include nitrogen, carbon dioxide, helium, argon, various chlorofluorocarbon gases, and mixed gases thereof. When the contacting step is performed under a specific gas atmosphere including the air atmosphere, a preferable pressure is 0.0001 atm or more and 10 atm or less.

Next, in the light irradiation step, as illustrated in FIG. 7C, the curable composition 202 is irradiated with light (irradiation light) 205 through the mold 204. In more detail, the curable composition 202 filled in the fine pattern of the mold 204 is irradiated with the light 205 through the mold 204. Thereby, the curable composition 202 filled in the fine pattern of the mold 204 is cured by the light 205 and becomes a cured film 206 having a pattern shape.

Here, the light 205 emitted to the curable composition 202 filled in the fine pattern of the mold 204 is selected in accordance with the sensitivity wavelength of the curable composition 202. Specifically, it is preferable to appropriately select and use ultraviolet rays, X-rays, electron beams, or the like having a wavelength of 150 nm or more and 400 nm or less.

Among these, the light 205 is particularly preferably ultraviolet rays. This is because many commercially available curing aids (photopolymerization initiators) are compounds that are sensitive to ultraviolet rays. Here, examples of light sources that emit ultraviolet rays include a high-pressure mercury lamp, an ultra-high-pressure mercury lamp, a low-pressure mercury lamp, a deep-UV lamp, a carbon arc lamp, a chemical lamp, a metal halide lamp, a xenon lamp, and the like. Further, examples thereof include a KrF excimer laser, an ArF excimer laser, an F2 excimer laser, and the like, but the ultra-high pressure mercury lamp is particularly preferable. Further, the number of light sources to be used may be one or two or more. In addition, when light irradiation is performed, it may be performed on the entire surface of the curable composition 202 filled in the fine pattern of the mold 204 or may be performed on only a partial region.

Further, the light irradiation step may be performed a plurality of times intermittently over the entire region on the substrate 201, or may be continuously emitted to the entire region. Furthermore, a region A may be irradiated in the first irradiation step, and a region B different from the region A may be irradiated in the second irradiation step.

Next, in the mold release step, as illustrated in FIG. 7D, the cured film 206 having a pattern shape is separated from the mold 204. Thereby, the cured film 206 having a pattern shape that is an inversion of the fine pattern formed on the mold 204 in the light irradiation step is obtained in a self-supporting state. The cured film remains also in concave portions of a concavo-convex pattern of the cured film 206 having a patterned shape, and this film will be referred to as a residual film 207.

A method of separating the cured film 206 having a pattern shape and the mold 204 is not particularly limited as long as a portion of the cured film 206 having a pattern shape is not physically damaged during separation, and various conditions and the like are not also particularly limited. For example, the mold 204 may be peeled off by fixing the substrate 201 (substrate to be processed) and moving the mold 204 away from the substrate 201. Alternatively, the mold 204 may be fixed and the substrate 201 may be moved away from the mold 204 and then peeled off. Alternatively, both may be pulled and peeled off in opposite directions.

By sequentially performing the above-described steps on a plurality of pattern formation regions (imprint regions), it is possible to obtain the cured film 206 having a desired concavo-convex pattern shape (a pattern shape based on the concavo-convex shape of the mold 204) at a desired position on the substrate 201.

Further, the processing apparatus in the present embodiment is not limited to an imprint apparatus, but can be mounted in, for example, a mold cleaning apparatus or a replica manufacturing apparatus that manufactures a mold replica. The replica manufacturing apparatus has the same configuration (also including functional units and a hardware configuration) as the imprint apparatus.

### Example Related to Article Manufacturing Method

An article manufacturing method according to this example is suitable for manufacturing articles such as micro devices such as semiconductor devices and elements having fine structures. The article manufacturing method according to this example includes a step of forming a pattern on a composition applied to a substrate using the above-described imprint apparatus (a step of performing processing on the substrate), and a step of processing the substrate having the pattern formed therein in this step. Further, such a manufacturing method includes other well-known steps (oxidation, film formation, deposition, doping, flattening, etching, composition peeling-off, dicing, bonding, packaging, and the like). The article manufacturing method according to this example is advantageous in terms of at least one of article performance, quality, productivity, and a production cost as compared to methods of the related art. In the article manufacturing method in this example, before imprint processing performed by the imprint apparatus is started, a removing step of removing residuals of a mold (die, master) using the above-described removal apparatus is performed. That is, when the imprint processing is performed, a mold in which residuals have already been removed and a liquid-repellent layer has been formed on a mesa side wall of the mold is used.

A cured material pattern molded using an imprint apparatus is used permanently in at least some of various articles, or used temporarily when various articles are manufactured. The articles include an electric circuit element, an optical element, MEMS, a recording element, a sensor, a mold, and the like. Examples of the electric circuit element include a volatile or nonvolatile semiconductor memory such as a DRAM, an SRAM, a flash memory, and an MRAM, and a semiconductor element such as an LSI, a CCD, an image sensor, and an FPGA. Examples of the mold include a mold for substrate processing such as imprinting, and the like.

The cured material pattern can be used as it is as a constituent member of at least a portion of the above-described article, or can be used temporarily as a composition mask. After etching, ion implantation, or the like is performed in a substrate processing step, the composition mask is removed.

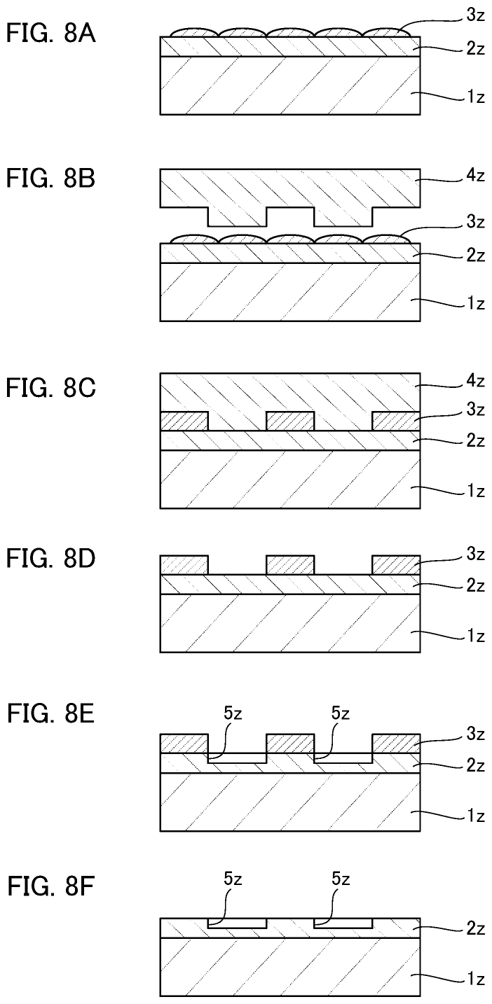

Next, a specific article manufacturing method will be described with reference to FIG. 8. As shown in FIG. 8A, a substrate 1z such as a silicon substrate on which a workpiece 2z such as an insulator is formed is prepared, and then a composition 3z is applied onto the surface of the workpiece 2z by an inkjet method or the like. Here, a state in which a plurality of droplet-shaped compositions 3z are applied onto the substrate 1z is shown.

As shown in FIG. 8B, a mold 4z is disposed such that a side having a concavo-convex pattern formed thereon faces the composition 3z on the substrate 1z. As shown in FIG. 8C, the substrate 1z to which the composition 3z has been applied is brought into contact with the mold 4z, and pressure is applied (contact step). The composition 3z is filled into a gap between the mold 4z and the workpiece 2z. In this state, when light is emitted as energy for curing through the mold 4z, the composition 3z is cured (curing step). At this time, in this example, it is possible to irradiate the composition with light at an irradiation amount for achieving an optimum degree of photopolymerization based on spectral sensitivity characteristics acquired within the apparatus.

As shown in FIG. 8D, when the composition 3z is cured, and then when the mold 4z and the substrate 1z are separated from each other, the cured material pattern of the composition 3z is formed on the substrate 1z (pattern forming step, molding step). The cured material pattern has a shape in which the concave portions of the mold 4z correspond to the convex portions of the cured material, and the convex portions of the mold 4z correspond to the concave portions of the cured material, that is, a concavo-convex pattern of the mold 4z is transferred to the composition 3z.

As shown in FIG. 8E, when etching is performed using the cured material pattern as an etching-resistant mask, portions of the surface of the workpiece 2z where there is no cured material or there is a thin remaining cured material are removed, forming grooves 5z. As shown in FIG. 8F, when the cured material pattern is removed, it is possible to obtain an article in which the grooves 5z are formed on the surface of the workpiece 2z. Although the cured material pattern is removed here, the cured material pattern may be used as a film for interlayer insulation included in a semiconductor element or the like, that is, as a constituent member of an article without being removed even after processing. Although an example in which a mold for circuit pattern transfer provided with a concavo-convex pattern is used as the mold 4z has been described, a planar template having a planer portion having no concavo-convex pattern may be used.

Although preferred embodiments of the present invention have been described above, the present invention is not limited to these embodiments, and various modifications and changes can be made within the scope of the gist. Further, the embodiments described above may be implemented in combination.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-086963, May 26, 2023, which is hereby incorporated by reference wherein in its entirety.

What is claimed is:

1. A removing method of removing a residual attached to a mold which includes a base having a main surface and a convex portion provided on the main surface and in which a concavo-convex pattern formed on an upper surface of the convex portion is pressed against a curable composition, the removing method comprising:
removing the residual,
wherein the removing of the residual includes removing the residual by dissolving a liquid-repellent layer formed on at least a side surface of the convex portion with a predetermined solvent.

2. The removing method according to claim 1, wherein the liquid-repellent layer includes a polymer having a fluorocarbon chain.

3. The removing method according to claim 1, wherein the removing of the residual includes dissolving the liquid-repellent layer so that a film thickness of the liquid-repellent layer is 3 nm or more.

4. The removing method according to claim 1, wherein the predetermined solvent is a volatile solvent that dissolves a polymer having a fluorocarbon chain.

5. The removing method according to claim 1, wherein the predetermined solvent includes at least one of a hydrofluoroether, a perfluorocarbon, and a hydrofluorocarbon.

6. The removing method according to claim 1, further comprising forming a protective layer that prevents the liquid-repellent layer from being formed on at least an outer peripheral portion of the concavo-convex pattern in the mold.

7. The removing method according to claim 1, further comprising:
forming the liquid-repellent layer on at least the side surface of the convex portion of the mold,
wherein the liquid-repellent layer is formed after the protective layer is formed.

8. The removing method according to claim 7, further comprising:
removing the protective layer and the liquid-repellent layer formed on a portion of the protective layer,
wherein the protective layer and liquid-repellent layer formed on a portion of the protective layer are removed after the liquid-repellent layer is formed.

9. The removing method according to claim 8, wherein the residual is removed after the protective layer and liquid-repellent layer formed on a portion of the protective layer are removed.

10. A removal apparatus configured to remove a residual attached to a mold which includes a base having a main surface and a convex portion provided on the main surface and in which a concavo-convex pattern formed on an upper surface of the convex portion is pressed against a curable composition, the removal apparatus comprising:
a stage that is able to move while holding the mold; and
a first removal unit configured to remove the residual by dissolving a liquid-repellent layer formed on at least a side surface of the convex portion with a predetermined solvent.

11. The removal apparatus according to claim 10, wherein the liquid-repellent layer includes a polymer having a fluorocarbon chain.

12. The removal apparatus according to claim 10, wherein the liquid-repellent layer has a film thickness of 3 nm or more after the residual is removed.

13. The removal apparatus according to claim 10, wherein the predetermined solvent is a volatile solvent that dissolves a polymer having a fluorocarbon chain.

14. The removal apparatus according to claim 10, wherein the predetermined solvent includes at least one of a hydrofluoroether, a perfluorocarbon, and a hydrofluorocarbon.

15. The removal apparatus according to claim 10, further comprising a first forming unit configured to form a protective layer configured to prevent the liquid-repellent layer from being formed on at least an outer peripheral portion of the concavo-convex pattern in the mold.

16. The removal apparatus according to claim 10, further comprising a second forming unit configured to form the liquid-repellent layer on at least the side surface of the convex portion of the mold.

17. The removal apparatus according to claim 15, further comprising a second removal unit configured to remove the protective layer and the liquid-repellent layer formed on a portion of the protective layer.

18. An imprint apparatus configured to form a pattern of a curable composition in a plurality of pattern formation regions on a substrate by using a mold configured to include a base having a main surface and a convex portion provided on the main surface and has a concavo-convex pattern formed on an upper surface of the convex portion, the imprint apparatus comprising:
an ejection device configured to eject the curable composition onto the substrate;
a substrate stage that is able to move while holding the substrate; and
a removal apparatus configured to include a stage that is able to move while holding the mold and a first removal unit configured to remove a residual attached to the mold by dissolving a liquid-repellent layer formed on at least a side surface of the convex portion with a predetermined solvent.

19. A replica manufacturing apparatus configured to manufacture a replica of a mold configured to include a base having a main surface and a convex portion provided on the main surface and has a concavo-convex pattern formed on an upper surface of the convex portion, the replica manufacturing apparatus comprising:
an ejection device configured to eject a curable composition onto a substrate;
a substrate stage that is able to move while holding the substrate; and
a removal apparatus configured to include a stage that is able to move while holding the mold and a first removal unit configured to remove a residual attached to the mold by dissolving a liquid-repellent layer formed on at least a side surface of the convex portion with a predetermined solvent.

20. An article manufacturing method performed by an imprint apparatus configured to form a pattern of a curable composition in a plurality of pattern formation regions on a substrate by using a mold configured to include a base having a main surface and a convex portion provided on the main surface and has a concavo-convex pattern formed on an upper surface of the convex portion,
the imprint apparatus including
an ejection device configured to eject the curable composition onto the substrate,
a substrate stage that is able to move while holding the substrate, and
a removal apparatus configured to include a stage that is able to move while holding the mold and a first removal unit configured to remove a residual attached to the mold by dissolving a liquid-repellent layer formed on at least a side surface of the convex portion with a predetermined solvent, and
the article manufacturing method comprising:
forming the concavo-convex pattern on the substrate by using the imprint apparatus;
processing the substrate on which the pattern has been formed in the forming of the concavo-convex pattern by using the imprint apparatus; and
manufacturing an article from the substrate processed in the processing of the substrate by using the imprint apparatus.
